(19) United States
(12) Patent Application Publication
(10) Pub. No.: US 2004/0020760 A1
(43) Pub. Date: Feb. 5, 2004

(54) Pulsed highly ionized magnetron sputtering

(76) Inventor: Vladimir Kouznetsov, Nynashamn (SE)

Correspondence Address: NIXON & VANDERHYE, PC, 1100 N GLEBE ROAD, 8TH FLOOR, ARLINGTON, VA, 22201-4714, US

(21) Appl. No.: 10/311,709

(22) PCT Filed: Jun. 19, 2001
(86) PCT No.: PCT/SE01/01416

(30) Foreign Application Priority Data
Jun. 19, 2000 (SE) 0002305-1

(51) Int. Cl. C23C 14/35

(52) U.S. Cl. 204/192.12; 204/298.16; 204/298.19; 204/298.08

(57) ABSTRACT

When using pulsed highly ionized magnetic sputtering for reactive deposition the pressure of the reactive gas in the area of the electrodes is drastically reduced by designing the anode electrode as a tube (3) having an opening facing the surface of the cathode (7) and an opposite opening facing the process chamber (11). The work piece (13) is placed in the process chamber which is connected (31) to a vacuum system and to which the reactive gas is supplied (29). The sputtering non-reactive gas is supplied (23) in the region of the cathode. Inside the anode tube the ions are guided by a stationary magnetic field generated by at least one coil (27) wound around the anode, the generated magnetic field thus being substantially parallel to the axis of the anode tube. The anode tube can be separated from the process chamber by a restraining device such as a diaphragm (41) having a suitably sized aperture or a suitably adapted magnetic field arranged at the connection of the anode with the process chamber. By the reduction of the pressure of the reactive gas at the cathode and anode the formation of compound layers on the surfaces of the electrodes between which the magnetron discharges occur is avoided resulting in stable discharges and a very small risk of arcing. Also, the neutral component in the plasma flow can be prevented from reaching the process chamber. By suitably operating the device e.g. sputtering of coatings in deep via holes for high density interconnections on semiconductor chips can be efficiently made.

### TECHNICAL FIELD

The present invention relates to methods and devices for coating working pieces by pulsed highly ionized magnetron sputtering, in particular for sputtering metals and for reactive sputtering.

### BACKGROUND

In coating processes using sputtering a vapour is created, the atoms of which are arranged to hit a substrate to be coated. The vapour is created by bombarding a target with ions derived from a partly ionized gas or gas mixture which comprises an inert gas, usually argon or a mixture of an inert gas with a reactive gas, typically argon and nitrogen or argon and oxygen. The gas ionisation is created by making an electric discharge, thereby producing electrons ionizing the gas. In magnetically enhanced or magnetron sputtering a magnetic field is created in such a way as to trap and concentrate the electrons produced in the electric discharge to form an electron cloud. This electron cloud, which for a suitable design of the magnetic field will be located at the surface of the target and have a high density of electrons, will then cause ionisation of the sputtering gas in the region close to the target surface. The target has an electric potential that is negative compared to the region in which the electron cloud is formed and will thereby attract positive ions to move with a high velocity towards the target. The impact of these ions at the target dislodges atoms from the target material. The dislodged atoms will then move into the region outside the target surface and into all of the space where the discharge is made and the target is located. Part of the dislodged atoms passing the electron cloud and plasma located near the surface of the target is ionized. The atoms and possible ions will finally be deposited on the walls of said space and thus also on the surface of the substrate. In the sputtering chamber a pressure somewhat lower than the atmospheric pressure is usually maintained, e.g. in the order of milliTorrs, e.g. in the range of 1·10³ to 5·10³ Torr.

Presently, one of the main development lines of magnetron sputtering deposition is directed to methods and apparatus for ionized sputter deposition and in particular to ionized reactive magnetron sputtering deposition.

An efficient method of sputtering and vapour ionization is disclosed in the published International patent application WO 98/40532. This prior method allows the formation of a fully ionized plasma located at and in the region in which electrons are trapped by a magnetron magnetic field. The method as well allows the formation of a highly ionized plasma of sputtered metal where the rate of ionization of the metal vapour is about 80%, see 35V. Kouznetsov et al., Surf. Coat. Techn., Vol. 122, 1999, pp. 290-293. However, this method cannot be used for reactive magnetron sputter deposition.

For magnetron sputtering deposition of metals it has been demonstrated that ionized metal fluxes generated by the method disclosed in the cited International patent application can be used for efficiently filling trenches and vias of submicron dimensions having a high aspect ratio, i.e. having a high ratio of the depth to width, on semiconductor chips, see the cited article for V. Kouznetsov et al. and also S. M. Rossnagel, J. Hopwood, J. Vac. Sci. Techn., B 12, 1994, p. 449, and S. M. Rossnagel, J. Hopwood, Appl. Phys. Lett., Vol. 63, 1993, p. 3285. Metal deposition of e.g. Al, Cu into such small or narrow structures is used for for example producing high-density interconnections using vias in electronic boards and chips. Also, highly ionized fluxes of metal can be used for efficient sputtering of ferromagnetic materials, see M. Yamashita, J. Vac. Sci. Techn., Ay, 1989, p. 152, and to modify the properties of thin films by energetic ions.

As has already been mentioned, the prior method of sputtering and vapour deposition according to the cited International patent application has a drawback by not being suitable for reactive metal sputtering. In particular it cannot provide highly ionized reactive magnetron sputtering deposition of metal oxides, particularly the deposition of coatings of alumina, A₂O₃. This drawback is due to the formation of compound layers at the surface of the electrodes between which the magnetron discharged is made. The compound layers can for some substances used in the sputtering be electrically isolating or have other unfavourable electric characteristics resulting in an arc discharge being formed instead the desired magnetron discharge. Another drawback of the formation of compound layers such as of Al₂O₃ on the surface of the target is that a lower deposition rate is obtained, this being caused by several physical effects. Thus, the sputtering yield for alumina is lower than that for aluminium and the secondary emission coefficient for the oxide is higher than that of the metal. The latter effect results in that the impedance of the plasma drops, due to the injection of extra secondary electrons and the fact that ions that bombard the target surface have a smaller energy which reduces the sputtering flux and hence the net deposition rate even more.

Presently, coatings of alumina for cutting tools are produced by chemical vapour deposition, CVD, see e.g. H. G. Prengel, W. Heinrich, G. Roder, K. H. Wendt, Surf. Coat. Techn., 68/69, 1994, p. 217. Typical substrate temperatures of alumina used in CVD are about 1000° C. These very high temperatures of the substrates limit the use of substrates to sintered materials such as cemented carbide and do not allow depositions on hardened high speed steel without softening it.

It has been demonstrated that the formation temperature of alumina can be drastically reduced in the case where fluxes of reactive Al-ions are employed to increase the energy at the substrate, see Zywitski et al., Surf. Coat. Techn. Vol. 82, 1996, pp. 169-175. It means that in order to have success in further reducing the formation temperature of alumina on work pieces it is necessary to increase the rate of metal vapour ionization in the vicinity of the surface of the work piece. Zywitski et al. used in depositing alumina magnetron sputtering cathodes connected to a bipolar pulse generator operating at a low frequency of 40 kHz to e.g. be compared to RF-enhanced magnetrons operating at frequencies of 13.56 MHz. This method has a very low rate of ionization of Al-atoms compared to the method of the cited International patent application but it still gives a significant reduction of the temperature required for the work piece. Thus, it can be foreseen that the method described in the cited International patent application and having a high rate of metal vapour ionization could give very good results in depositing for producing hard surface layers or coatings on metals, in particular for depositing alumina, provided that the problems associated with formation of compound layers or coatings and particularly electrically non-conductive layers or coatings on the cathode of the magnetron could be eliminated or at least considerably reduced.

A method for reactive magnetron sputtering is disclosed in T. M. Pang, M. Schreder, B. J-Teinz, C. Williams, G. N. Chaput, “A modified technique for the production of the Al₂O₃ by [symbol] current reactive magnetron sputtering”., J. Vac. Sci. Techn., Vol. A7(3), May/June [symbol] pp. 1254-1259. In this method a shielding chamber is used accommodating the target and the inlets of sputtering gas. The shielding chamber provides separation of the sputtering gas and the reactive gas and its inner surface provides a gettering surface for excess oxygen in the vicinity of the target surface.

### SUMMARY

It is an object of the present invention to provide methods and devices allowing generation of intensive, highly ionized metal plasma flows without formation of compound layers on the electrodes between which a magnetron discharge occurs.

A problem, which the inventions thus intends to solve, is how to efficiently coat a work piece by magnetron reactive sputtering.

Thus, generally in a method and device for pulsed highly ionized magnetic sputtering deposition an ultralow pulse frequency of the magnetron discharges is used which preferably is in the order of some tenths to hundreds of Hz. The method and device avoids the formation of compound layers on the surfaces of the electrodes between which the magnetron discharges occur by drastically reducing the pressure of the reactive gas in the area of the electrodes. This drastic pressure reduction is achieved by designing the anode electrode forming the sidewalls of the discharge chamber as a tube which preferably is cylindrical but can have any other suitable shape such as a conical or tapering shape and has an opening facing the surface of the cathode and an opposite opening facing the process chamber. The work piece is placed in the process chamber which is connected to a vacuum system and to which the reactive gas is supplied. The sputtering non-reactive gas is supplied in the region of the cathode electrode. Inside the anode tube the ions are guided by a stationary or constant magnetic field generated by at least one coil wound around the anode, the generated magnetic field thus being substantially parallel to the axis of the discharge chamber or anode tube inside the tube, at least at the axis of the tube. The anode tube can be separated from the process chamber by a restraining device such as a diaphragm having a suitably sized hole and/or a suitably adapted magnetic field arranged at the connection of the anode with the process chamber.

Additional objects and advantages of the invention will be set forth in the description which follows, and in part will be obvious from the description, or may be learned by practice of the invention. The objects and advantages of the invention may be realized and obtained by means of the methods, processes, instrumentalities and combinations particularly pointed out in the appended claims.

### BRIEF DESCRIPTION OF THE DRAWINGS

While the novel features of the invention are set forth with particularly in the appended claims, a complete understanding of the invention, both as to organization and content, and of the above and other features thereof may be gained from and the invention will be better appreciated from a consideration of the following detailed description of non-limiting embodiments presented hereinbelow with reference to the accompanying drawings, in which:

FIG. 1 is a cross-sectional view of a reactive sputtering device,

FIG. 2 is a diagram of the intensity of neutral flux at the axis of an anode tube as a function of the distance from the plane through a cathode or target, and

FIG. 3 is a diagram of the deposition rate of sputtered atoms deposited on the internal walls of an anode tube as a function of the distance from the plane through a cathode or target and of the pressure of a reactive gas as a function of the same quantity.

### DETAILED DESCRIPTION

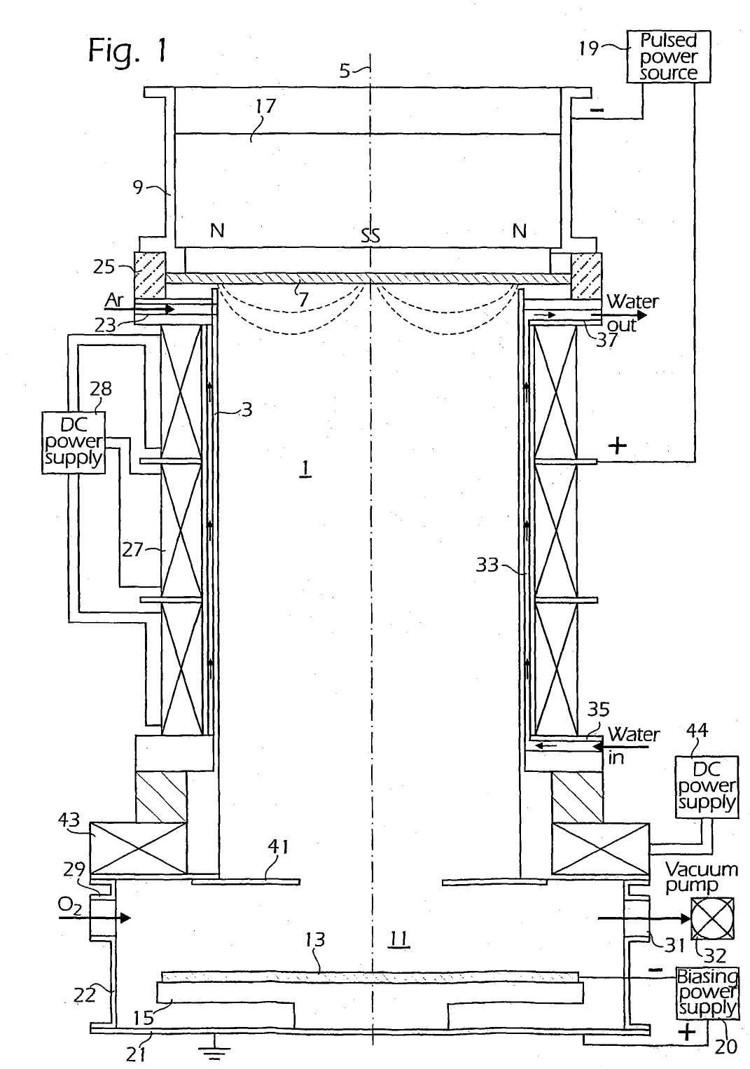

In FIG. 1 a sectional view of a device for magnetically enhanced sputtering having a specially designed ion source is shown, the view being taken in a plane through an axis of the device. A discharge chamber 1 is formed in the interior of a cylindrical housing having a sidewall 3 made of some suitable metal, e.g. stainless steel plate or possibly aluminium, copper or titanium, the sidewall of the housing thus being electrically conducting and forming an anode used in producing the electrical discharges used in magnetron sputtering. The discharge chamber 1 and the sidewall 3 have a common symmetry axis 5 forming the axis of the device and most of the components of the device are also arranged symmetrically in relation to this axis. A flat target plate 7 is located at one end of the discharge chamber 1 forming an end wall thereof and is clamped to a support 9 made of some electrically conducting, diamagnetic material. The target 7 is in the embodiment shown a circular plate made of a material, which is to be applied to an object or work piece or which is a component of a material to be applied to an object. At the opposite end of the discharge chamber an opening into a process chamber 11 is provided. In the process chamber 11 is the substrate or work piece 13 which is to be coated located. The work piece 13 is attached to an electrically isolating support 15.

At a small distance of the rear side of the target 7, at that surface which is directed away from the discharge chamber 1, a magnet assembly 17 is mounted so that magnetic north poles are arranged at the periphery of the target 7 and magnetic south poles at the center of the target or vice versa. The magnetic field lines of the magnet assembly 17 thus pass from the periphery of the target plate 7 to the center thereof or alternatively from the center to the periphery of the target plate. Obviously, the magnetic field is most intense at the poles of the magnet assembly 17. At the region between the periphery and the center of the target 7 there is thus a smaller intensity of the magnetic field. The cathode magnet assembly produces a constant or possibly slowly varying magnetic field, the assembly comprising e.g. permanent magnets that can be fixed or arranged to slowly perform a rotating movement about the axis 5.

An electric power supply 19 has its positive terminal connected to the anode or electrically conducting sidewalls 3 and its negative terminal connected to the target 7 through the support 9, the target thus having a more negative potential than the anode and forming a cathode. The power supply 19 generates high voltage pulses resulting in electric discharges creating electrons ionizing the gas in the discharge chamber 1, in particular in the vicinity of the surface of the cathode 7. The pulsed power supply 19 can be operated as suggested in the cited International patent application WO 98/40532 using pulses with ultra high power, the pulses being applied at a very low frequency.

The substrate 13 can have a relatively small constant negative electric potential such as in the range of 0-100 V as biassed by a DC power supply 20 whereas the metal walls 21, 22 behind or under and at the side of the substrate can be connected to ground. Thereby the anode 3 will also be grounded. Owing to the magnetic field from the magnet assembly 17 electrons and ions will to some extent be trapped as a plasma in a region at the target 7, the region being annular and located in the low-intensity portion of the magnetic field.

Gas inlets 23 for a suitable process or sputtering gas to be ionized such as argon are located in the target end of the discharge chamber 1, fairly close to the surface of target, passing through holes in the anode wall 3. The anode wall 3 ends at the cathode at some small distance thereof such as 1-3 mm. The anode tube 3 and attached metal parts are attached to and electrically isolated from the cathode support 9 by a ring 25 of an electrically isolating material.

The anode tube 3 has generally e.g. a cylindrical shape such as a circular cylinder but other shapes can be used. It is in the preferred case elongated, e.g. having a length of about twice its diameter, but generally it can have a length of 0.5-3 diameters, the diameter generally being taken as the characteristic cross-dimension of the anode tube. It can have a diameter substantially equal to the diameter of the region in which the electrons and ions are trapped by the magnetron magnetic field, e.g. about 150 mm for a cathode diameter of 175 mm. The length or height of the anode will then in a preferred case be about 300 mm.

Inside the anode tube 3, a substantially longitudinal, constant magnetic field is created by a solenoid assembly 27 connected to a DC power supply 28 and having windings around the anode tube, this anode magnetic field guiding particles of the plasma generally in the axial direction of the anode tube, i.e. parallel to the axis 5. In the embodiment shown the anode solenoid assembly 27 comprises three identical segments which can be energized by the same electrical DC current or by different DC current intensities to provide a magnetic field having a desired shape and intensity inside the anode tube.

At the work piece end, the process chamber 11 has a larger diameter than the anode tube 3 to allow receiving substrates 13 having diameters larger than the anode diameter, e.g. about 175 mm. In the process chamber 11, inlets 29 for a reaction gas such as O₂ are provided, these inlets located fairly close to radial edges of the workpiece 13. Here also, an outlet 31 is provided which is attached to a vacuum system or pump 32 for maintaining, when the device is in operation, a low pressure in the process and discharge chambers.

The anode wall 3 can be cooled by having water flow in channels 33 in the wall connected to a water inlet 35 and a water outlet 37. Also, other walls or wall portions of the discharge chamber and of the process chamber can be cooled by water if required.

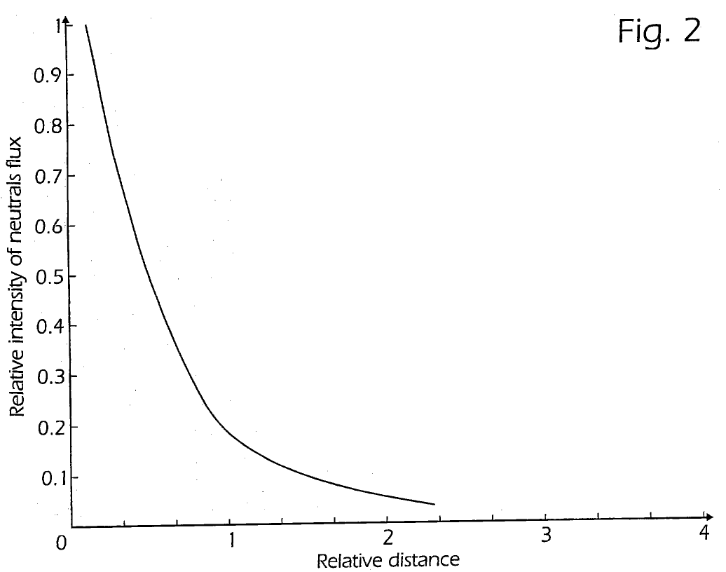

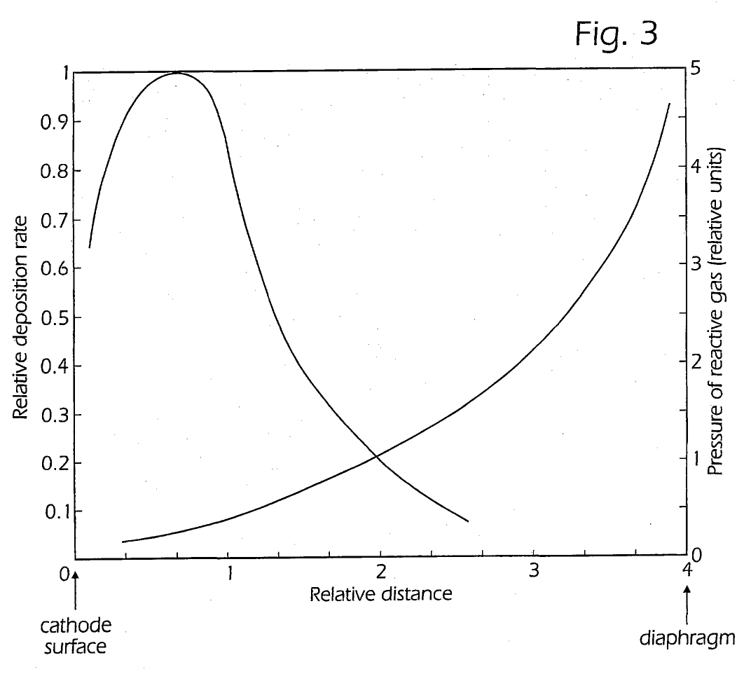

First, the separation of neutrals, i.e. neutral particles and atoms, will be discussed. If the axial component B_{m∥} of the magnetron magnetic field Bₘ, i.e. the component parallel to the axis of the cathode 7 and the anode tube 3 of the magnetic field generated by the magnet assembly 17, and the axial component B_{c∥} of the magnetic field B_{c} generated by the anode magnet assembly 27 have opposite directions, this condition being essential to the operation of the device as will be demonstrated hereinafter, the plasma is concentrated in the region of the anode axis 5. Neutral vapour is spread into all the volume of the anode tube 3. Plasma and neutral vapour flow in the direction from the cathode 7 to the process chamber 11, both by diffusion effects and the effect of pumping from the process chamber 11, at the outlet 31. The intensity of the neutral stream decreases in the direction from the cathode 7, as is illustrated by the diagram of FIG. 2, because neutral atoms and particles of the neutral vapour are deposited on the internal wall of the anode tube 3, on their way towards the process chamber 11, see the curve of FIG. 3 having a peak for a small distance of the cathode.

The intensity of the plasma does not decrease along the axis, with the distance of the cathode 7, because plasma losses are prevented by the magnetic field generated by the anode magnet assembly 27.

In order to even more decrease the flow of neutrals without any substantial losses of EIPC; the equivalent integral plasma current, as will be defined hereinafter, the outlet opening of the anode 3, i.e. the opening which is located distant of the cathode 7, can be made to restrict this flow by arranging a restraining device at that opening. Thus, as illustrated in FIG. 1, a physical aperture is provided by arranging an annular, electrically conducting shielding plate 41 that can be located at the place where the discharge chamber 1 opens into the process chamber 11. In the shielding plate 41 a central opening is provided having a diameter smaller than the inner diameter of the anode sidewall 3, e.g. in a typical set-up the central opening having a diameter in the range of 70-80 mm. Such an aperture also restricts the flow of reactive or process gas from the process chamber into the discharge chamber.

Another way of controlling the flow between the discharge chamber 1 and the process chamber 11 comprises using an additional solenoid 43, see FIG. 1, which is connected to a DC power supply 44 and like the shielding plate 41 is located at the connection of the anode sidewall 3 with the process chamber. The additional solenoid 43 is also wound around the anode tube 3 and comprises more turns per length unit in the axial direction than the windings of the anode solenoid assembly 27. It produces a constant magnetic field which has the same general axial direction as that generated by the anode solenoid assembly 27 and which deforms the total magnetic field to produce a concentrating or focusing effect for electrically charged particles moving out of the lower end region of the discharge chamber 11. The two restraining/concentrating devices 41, 43 can be used separately but are advantageously used together in the same device as illustrated in the figure. The additional intense magnetic field produced by the solenoid 43 compresses the plasma stream in the region of the outlet opening of the anode tube 3 towards the axis and thereby the opening of the diaphragm 41 can be made smaller resulting in no substantial losses of the plasma flow but with greater losses of the neutral flow and more efficiently stopping the flow of process or reactive gas into the discharge chamber.

Thus, generally in the device as described above, the outlet opening of the plasma source, the plasma source comprising the magnetron sputtering cathode and the anode chamber, is displaced to be located at a significant distance from the cathode and a longitudinal or axial constant magnetic field inside the anode is established with a selected direction, these details resulting in a structure allowing the separation of sputtered metal atoms from the metal plasma. By further making the plasma source include outlet restricting/concentrating devices, the flow at said outlet is restrained which in turn enhances the separation of neutral particles from the electrically charged particles. The rate or efficiency of separation is basically defined by the length of the anode 3 and the diameter of said outlet opening. The plasma source thus is here taken to comprise the magnetron sputtering cathode 7 and the anode tube 3 and where it/they are used, the restraining device or devices 41, 43 at the outlet of the anode tube 3.

Second, the chemisorption of reactive gas in the volume of the discharge chamber 1 will be discussed. For reactive sputtering deposition it is necessary, to give an efficient sputtering process, to significantly reduce the concentration of reactive gas in the region at the magnetron sputtering cathode 7. The device as described above also allows it. The following processes occur in the volume defined by the cathode 7, the interior wall of the anode tube 3 and the outlet opening of the anode tube. Reactive gas which enters this volume from the process chamber 11 is efficiently removed from the volume by a chemisorption reaction on the interior surface of the anode 3 and on the interior wall of the shielding plate 41 in the case where it is used. This is illustrated by the monotonously increasing curve of the diagram of FIG. 3 which is an approximative plot of the pressure of the reactive gas as a function of the distance from the cathode. The said surfaces of the volume will be coated with the metal of cathode 7. Thus for instance, they will be coated with aluminium for an aluminium cathode and with titanium for a titanium cathode. Aluminium is an efficient chemisorption or gettering substance for oxygen and titanium is an efficient chemisorption or gettering substance for both oxygen and nitrogen. The chemisorption effect results in a low or very small pressure of the reactive gas in the region of the cathode, as appears from the plot in FIG. 3. If the power of the magnetron discharges as delivered by the power supply 19 is set to a sufficient level for depositing sufficient amounts of the metal or the gettering substance on said walls, practically all reactive gas entering the volume will be absorbed by the deposited substance before entering the region at the cathode surface and the adjacent region of the anode interior surface. Since practically no gettering then occurs in these regions, the surfaces at these regions will remain electrically conductive during the operation of the device. Thus, the magnetron discharges can continue in substantially the same way as when starting the device between the constantly non-poisoned cathode and the constantly non-poisoned anode surface adjacent to the cathode. For instance, for oxygen as reactive gas, in the chemisorption electrically non-conducting oxides will be formed. Such oxides can be formed in the region adjacent the cathode but still to some very small extent since the chemisorption or gettering effect is obviously very intense there because of the very high rate of metal deposition so that every remaining amount of the reactive gas will be absorbed.

The successive steps executed when operating the sputtering device as described above can be as follows:

Switch on the DC power supply, not shown, of the solenoid assembly 27 to start generating the constant anode magnetic field.

Close a shutter, not shown, separating the work piece 13 from the plasma beam.

Supply sputtering gas through the inlets 23 to the discharge chamber 1.

Start the magnetron discharge at a first power level by switching on and setting the power supply 19 to deposit an initial amount of metal to act as a gettering substance on the walls of the discharge chamber 1.

Increase the power of the magnetron discharge up to a second higher level defined by the desired deposition rate and by the concentration of reactive gas necessary for depositing the desired compound.

Supply the reactive gas to the process chamber 11 through the inlets 29.

Increase the pressure of the reactive gas up to a value defined by the desired deposition rate and by the desired compound to be deposited.

Open the shutter separating the work piece 13 from the plasma beam.

After the operation of the device as described above for a time period sufficient to give a desired thickness of the layer deposited on the work piece 13 the following successive steps are executed:

Close the shutter separating the work piece 13 from the plasma beam.

Stop supplying reactive gas through the inlets 29.

Stop the magnetron discharge by switching off the power supply 19.

Switch off the power supply of anode solenoid assembly 27.

Stop supplying sputtering gas to the discharge chamber 1.

In a practical embodiment using oxygen as the reactive gas it was found that for a flat circular cathode 7 having a diameter of 150 mm connected to an anode tube 3 having an inner diameter of 175 and a length of 300 mm, in order to maintain a stable operation of the magnetron discharge an oxygen pressure of 2·10⁻-3·10⁻³ Torr is necessary to have an average power of 4 kW in the magnetron discharge and an opening of the shielding plate 41 having a diameter of 70 mm. If the magnetron discharge is produced according to the method proposed in the cited International patent application WO 98/40532 the device can provide a plasma stream of about 0.3 A, this plasma stream being used for depositing aluminium or titanium on the work piece.

In the magnetron sputtering device as described above an equivalent integral plasma current EIPC can be defined as the electrical charge per second, transported by ions in a plasma beam across a cross-section of the anode tube 3, the cross-section being perpendicular to the axis at the end of the anode tube. EIPC can be measured as ion saturation current collected by a planar large, negatively biassed collector having a diameter larger than the diameter of the plasma beam at the surface of the collector. The collector is then placed outside the anode 3 and the plane through the collector is perpendicular to the axis of the plasma beam. The operation of the sputtering device as described above will now discussed in some more detail.

In an experimental setup basically as depicted in FIG. 1, when varying the magnitude and direction of the stationary anode magnetic field produced by the solenoid assembly 27, it was found:

1. The value of EIPC strongly depends on the direction of the axial component B_{c∥} of the stationary magnetic field B_{c} generated by the anode coils 33 and the direction of the axial component B_{m∥} of the magnetron magnetic field Bₘ in the center of the magnetron cathode 7.

If B_{m∥} and B_{c∥} have opposite directions EIPC increases with increased B_{c∥}. The maximum value of EIPC corresponds to the case where B_{c∥} equals B_{m∥} at the surface of the cathode target 7. The value of EIPC in this case is a factor 10 higher than the value of EIPC for B_{c∥}=0.

If the directions of B_{m∥} and B_{c∥} coincide, EIPC decreases with increased B_{c∥}. The value of EIPC for the case where B_{c∥} and B_{m∥} are equal at the cathode surface is a factor 10 lower than the value of EIPC for B_{c∥}=0.

2. The spatial variation of the quantity EIPC strongly depends on the axial component B_{c∥} of the stationary magnetic field B_{c} generated by the anode coil 27 and the direction of the axial component B_{m∥} of the magnetron magnetic field in the center of the magnetron cathode.

If B_{m∥} and B_{c∥} have opposite directions the electrical current density of the plasma current has its highest values at the axis of the anode tube 3. In the plane of the shielding diaphragm 41 95% of the EIPC over this plane is constituted by the plasma current inside the region in the hole of the diaphragm, the hole having a diameter of 80 mm.

If the directions of B_{m∥} and B_{c∥} coincide, EIPC has its highest values in the region of the internal wall of the anode tube 3. In this case the EIPC over the hole of the diaphragm is practically equal to zero.

3. The minimum discharge pressure strongly depends on the axial component B_{c∥} of the stationary magnetic field B_{c} generated by the anode coils 27 and the direction of the axial component B_{m∥} of the magnetron magnetic field in the center of the magnetron cathode. If B_{m∥} and B_{c∥} have opposite directions and B_{m∥}=B_{c∥} the minimum discharge pressure is 4·10⁻⁴ Torr. If the directions of B_{m∥} and B_{c∥} coincide and B_{m∥}=B_{c∥} the minimum discharge pressure is 5·10⁻³ Torr.

For partial plasma ionization:

4. The intensity of neutral flux at the axis 5 of the anode tube 3 depends on the distance from the plane through the cathode 7 as shown by the diagram of FIG. 2.

5. The deposition rate of sputtered atoms deposited on the internal walls of the anode tube 3 depends on the distance from the plane extending through the cathode 7 as shown by the diagram of FIG. 3. The homogeneity of the layer deposited on the internal side of the diaphragm 41 is approximately constant in the case where the distance between the diaphragm and the cathode 7 exceeds the characteristic dimensions or dimensions of the cathode or target. For a flat, circular cathode the characteristic dimension obviously is the diameter.

In a first preferred method based on the findings as described above the following steps are executed:

1. Operating the magnetron circuits or power supply 19 to give magnetron discharges according to the method disclosed in the cited International patent application WO 98/40532 i.e. to give pulsed, ultra high power, magnetron discharges, with an average level of the pulsed power which can be varied.

2. Selecting the average power level of the magnetron discharges to give a high rate of ionization of sputtered metal vapour.

3. Separating the rest of neutral vapour of sputtered metal from the plasma at the cathode 7 by a stationary, anode magnetic field, as produced by the solenoid assembly 27, substantially directed along the axis 5 of the anode tube 3 and having a direction opposite that of the magnetic field of the magnetron, as produced by the magnet assembly 17, at the center of the cathode 7 and by the diaphragm 41 placed at the outlet or distant opening of the anode tube 3.

4. Selecting the intensity and direction of the anode magnetic field, by controlling the electric current flowing through the windings of the solenoids 27, to produce an intense flow of plasma through the opening of the diaphragm 41.

5. Supplying sputtering gas through the inlets 23 in the region of the cathode 7.

6. Establishing a pressure of sputtering gas in the discharge chamber 1 within a range of 4·10⁻⁴-10⁻² Torr, preferably about 7·10⁻⁴ Torr.

In a second preferred method the following steps are executed:

1. Operating the magnetron circuits or pulsed power supply 19 to give magnetron discharges according to the method disclosed in the cited International patent application, i.e. to give pulsed, ultra high power, magnetron discharges, with a variable average level of the pulsed power.

2. Selecting the average power level of the magnetron discharges to give a partial ionization of sputtered metal vapour, i.e. the average power level is in this method lower than in the first method.

3. Separating the neutral vapour of sputtered metal from the plasma by a stationary, anode magnetic field substantially directed along the axis 5 of the anode tube 3 and having a direction opposite that of the magnetic field of the magnetron at the center of the cathode 9 and by the diaphragm 41 placed at the outlet opening of the anode tube 3.

4. Depositing vapour of the sputtered metal on the internal surfaces of walls of the anode tube 3 with a gradient of the deposited layers along the walls and depositing vapour of the sputtered metal on the internal surface of the diaphragm 41, i.e. its surface facing the target 7. The deposited layers are used as a getter for reactive gas entering the discharge chamber 1 from the process chamber 11.

5. Selecting the intensity and direction of the anode magnetic field to produce an intense plasma flow through the opening of the diaphragm 41.

6. Supplying sputtering gas through the inlets 23 to the region of the cathode 7 and reactive gas through the inlets 29 to the process chamber 11.

7. Establishing a pressure of sputtering gas in the discharge chamber 1 and of reactive gas in the process chamber 11 within a range of 4·10⁻⁴-10⁻² Torr, preferably about 5·10⁻⁴ Torr.

8. Adjusting if required the average power level of the magnetron discharges to give a deposition of sputtered metal on the walls of the discharge chamber 1 for gettering all reactive gas entering the discharge chamber and to sputter traces of compound layers on the surface of the cathode 7 of the magnetron discharge.

It was found that when steps 1.-8. of the second method are executed, traces of compound layers formed on the cathode 7 and on the upper, inner wall of the anode tube 3, located near the cathode, are not noticeable and do not cause formation of arc discharges and furthermore do not result in any noticeable lowering of the cathode sputtering rate.

The second method described above has considerable advantages compared to the method disclosed in the article cited above by T. M. Pang et al. In the prior method the length of the shielding chamber, which provides gas separation and a gettering surface for excess oxygen in the vicinity of the target surface, is limited by losses of metal vapour on the walls of the shielding chamber, see FIG. 2 of the article. As can be seen the intensity of the vapour flux at a distance of 30 cm from the cathode is a factor 20 smaller than the initial intensity. In the second method as described herein the plasma flux of the 30 cm long anode tube 3 is a factor 10 higher than the flux obtained for a case without any anode magnetic field. It is important since the deposition process according to the second method provides a highly ionized plasma of sputtered metal.

As is obvious to anyone skilled in the art, the details of the device as described above can be modified without departing from the spirit of the invention. Thus, for example the magnetron sputtering cathode can have any suitable design such as planar rectangular, cylindrical or conical or it can be a sputtering gun. The cathode has in these embodiments an axis perpendicular to a front surface, the axis generally being some symmetry axis. The axis of the anode tube should preferably coincide with this axis.

While specific embodiments of the invention have been illustrated and described herein, it is realized that numerous additional advantages, modifications and changes will readily occur to those skilled in the art. Therefore, the invention in its broader aspects is not limited to the specific details, representative devices and illustrated examples shown and described herein. Accordingly, various modifications may be made without departing from the spirit or scope of the general inventive concept as defined by the appended claims and their equivalents. It is therefore to be understood that the appended claims are intended to cover all such modifications and changes as fall within a true spirit and scope of the invention.

1. A device for reactive magnetron sputtering comprising a plasma source including:
a pulsed power supply for applying voltage pulses between an anode and a cathode to make discharges between the anode and cathode producing electrons,
the cathode comprising a metal target and from which metal material is to be sputtered,
a first magnet assembly for providing a first magnetic field in a magnetron configuration at a surface of the target trapping the electrons in the magnetic field,
a discharge chamber containing the target and having sidewalls connected as the anode,
inlets into the discharge chamber for a sputtering gas to be ionized, and
a plasma outlet,
the device further comprising a process chamber connected to the plasma source at the plasma outlet for receiving plasma, the process chamber arranged to contain a work piece to be coated with material and the process chamber including:
inlets into the process chamber for a reactive or process gas, and
an outlet of the process chamber connected to a vacuum pump,
characterized in that the plasma source further includes a second magnet assembly for generating a constant second magnetic field which inside the discharge chamber is substantially parallel to an axis of the cathode and/or of the target or which has field lines at the surface of the target substantially all going out from or substantially all going into a surface of the target facing the discharge chamber, the second magnetic field guiding charged particles away from the cathode to produce a plasma flow, in particular a relatively well-defined plasma flow, flowing out of the plasma outlet into the process chamber.

2. A device according to claim 1, characterized in that the sidewalls of the discharge chamber comprise a substantially cylindrical, electrically conducting, inner surface having an axis substantially coinciding with an axis of the cathode.

3. A device according to claim 1, characterized in that the discharge chamber has a height or length of 0.5-3 diameters thereof.

4. A device according to claim 1, characterized in that the discharge chamber is elongated and in particular has a height or length of substantially twice its diameter.

5. A device according to claim 1, characterized in that the second magnet assembly comprise at least one solenoid having windings wound around the discharge chamber and connected to a DC power supply.

6. A device according to claim 1, characterized in that the first and second magnet assemblies generate magnetic fields which at a center of the surface of the target have opposite directions.

7. A device according to claim 1, characterized in that the discharge chamber has a first end located at the target and a second opposite end at the plasma outlet, opening into the process chamber, and that a restraining device is located at the second end and/or plasma outlet to restrain flow of neutral particles into the process chamber and/or flow of the reactive or process gas into the discharge chamber.

8. A device according to claim 7, characterized in that the restraining device comprises an aperture or shielding plate having an opening at the axis of the discharge chamber, the opening being smaller than a cross-sectional area of the discharge chamber at the second end thereof, the opening allowing a restricted flow between the discharge chamber and the process when the device is activated for sputtering a workpiece.

9. A device according to claim 1, characterized in that the discharge chamber has a first end located at the target and a second opposite end at the plasma outlet, opening into the process chamber, and that a concentrating device is located at the second end and/or plasma outlet concentrating a flow of electrically charged particles out of the discharge chamber.

10. A device according to claim 9, characterized in that the concentrating device comprises a third magnet assembly generating a relatively intense constant third magnetic field at the second end, the third magnetic field being substantially parallel to the axis of discharge chamber at the second end to make a flow of electrically charged particles out of the discharge chamber have a smaller cross-sectional area at the second end.

11. A device according to claim 10, characterized in that the third magnet assembly comprises a solenoid wound around the discharge chamber and having relatively many windings and being relative short in the direction of the axis of the discharge chamber.

12. A method of reactive, magnetron sputtering deposition, comprising the steps of:
applying voltage pulses between an anode and a cathode to make discharges between the anode and cathode producing electrons,
providing a metal target, from which metal material is to be sputtered, and connecting it to the cathode,
providing a first magnetic field in a magnetron configuration at a surface of the target trapping the electrons in the first magnetic field,
providing a sputtering gas at the vicinity of the target to make it be ionized by the electrons,
providing a work piece, on a surface of which the deposition is made,
providing a reactive or process gas at the vicinity of the work piece, and
evacuating gas from a place at the work piece to maintain a relatively low pressure at the work piece and at the target,
characterized by the additional step of providing a constant second magnetic field having directions, in a region at the surface of the target, substantially parallel to an axis of the target or having field lines at the surface of the target substantially all going out from or substantially all going into the surface of the target for guiding charged particles away from the cathode to produce a plasma flow, in particular a relatively well-defined plasma flow, flowing towards the work piece.

13. A method according to claim 12, characterized in that the second magnetic field has a significant extension along the axis of the target, particularly an extension corresponding to at least half a diameter of the target and preferably corresponding to between one and two diameters of the target.

14. A method according to claim 12, characterized by the additional step of physically restraining flow of particles and/or gases between spaces at the target and at the work piece, in particular restraining flow of the reactive or process gas towards the target and/or restraining flow of neutral particles away from the target.

15. A method according to claim 12, characterized by the additional step of concentrating a flow of charged particles moving away from the target at a place between spaces at the target and at the work piece.

16. A method according to claim 15, characterized in that in the additional step of concentrating a flow of charged particles a constant third magnetic field is provided having a relatively small extension along the axis of the target but having a relatively high intensity.
